(19) United States
(12) Patent Application Publication
(10) Pub. No.: US 2008/0143392 A1
(43) Pub. Date: Jun. 19, 2008

(54) ENVELOPE DETECTOR

(76) Inventor: JERRY WILLIAM YANCEY, ROCKWALL, TX (US)

Correspondence Address: HOVEY WILLIAMS LLP, 10801 Mastin Blvd., Suite 1000, Overland Park, KS, 66210, US

(21) Appl. No.: 11/611,316

(22) Filed: Dec. 15, 2006

(51) Int. Cl. H03K 5/153

(52) U.S. Cl. 327/62

(57) ABSTRACT

An envelope detector operable to detect and record the minimum and maximum values present in a data stream. In various embodiments, the envelope detector includes a memory operable to store first and second data values, a first comparator, and a second comparator. The first comparator is generally operable to compare the first data value to a first input from the data stream and output a first control signal to cause the memory to store the first input as the first data value if the first input is greater than the first data value. The second comparator is generally operable to compare the second data value to the second input from the data stream and output a second control signal to cause the memory to store the first input as the second data value if the first input is less than the first data value.

### BACKGROUND OF THE INVENTION

1. Field of the Invention

Embodiments of the present invention relate to methods and apparatuses for detecting the minimum and/or maximum data values present in a data stream. More particularly, various embodiments of the invention provide an envelope detector operable to detect and record the minimum and maximum values present in a data stream.

2. Description of the Related Art

Analog to digital converters, and other digital signal processing elements, often generate streams of data corresponding to received signals. Prior art systems have been developed to detect the minimum or maximum data values present in generated data streams to facilitate various processing methods. However, these systems do not enable detection of a complete data envelope, thereby inhibiting digital signal processing.

### SUMMARY OF THE INVENTION

Embodiments of the present invention solve the above-described problems and provide a distinct advance in the art of detecting the minimum and/or maximum data values present in a data stream. More particularly, various embodiments of the invention provide an envelope detector operable to detect and record the minimum and maximum values present in a data stream.

In various embodiments, the envelope detector includes a memory operable to store first and second data values, a first comparator, and a second comparator. The first comparator is generally operable to compare the first data value to a first input from a data stream and output a first control signal to cause the memory to store the first input as the first data value if the first input is greater than the first data value. The second comparator is generally operable to compare the second data value to the first input from the data stream and output a second control signal to cause the memory to store the first input as the second data value if the first input is less than the second data value. Such a configuration enables the envelope detector to generally simultaneously detect the maximum and minimum values within the data steam.

Other aspects and advantages of the present invention will be apparent from the following detailed description of the preferred embodiments and the accompanying drawing figures.

### BRIEF DESCRIPTION OF THE DRAWING FIGURES

A preferred embodiment of the present invention is described in detail below with reference to the attached drawing figures, wherein:

FIG. 1 is a block diagram of an envelope detector configured in accordance with various preferred embodiments of the present invention;

FIG. 2 is a schematic diagram showing some of the elements of the envelope detector of FIG. 1 in more detail; and

FIG. 3 is a schematic diagram showing an envelope detector configured in accordance with various other preferred embodiments of the present invention.

The drawing figures do not limit the present invention to the specific embodiments disclosed and described herein. The drawings are not necessarily to scale, emphasis instead being placed upon clearly illustrating the principles of the invention.

### DETAILED DESCRIPTION OF THE PREFERRED EMBODIMENTS

The following detailed description of the invention references the accompanying drawings that illustrate specific embodiments in which the invention can be practiced. The embodiments are intended to describe aspects of the invention in sufficient detail to enable those skilled in the art to practice the invention. Other embodiments can be utilized and changes can be made without departing from the scope of the present invention. The following detailed description is, therefore, not to be taken in a limiting sense. The scope of the present invention is defined only by the appended claims, along with the full scope of equivalents to which such claims are entitled.

Embodiments of the present invention provide an envelope detector 10 operable to detect the minimum and/or maximum data values present in a data stream. In some embodiments, the envelope detector 10 may be included within a digital signal processing system, such as the systems disclosed in commonly-owned U.S. patent application Ser. Nos. 11/311,204 and 11/311,205, each of which are incorporated herein by specific reference.

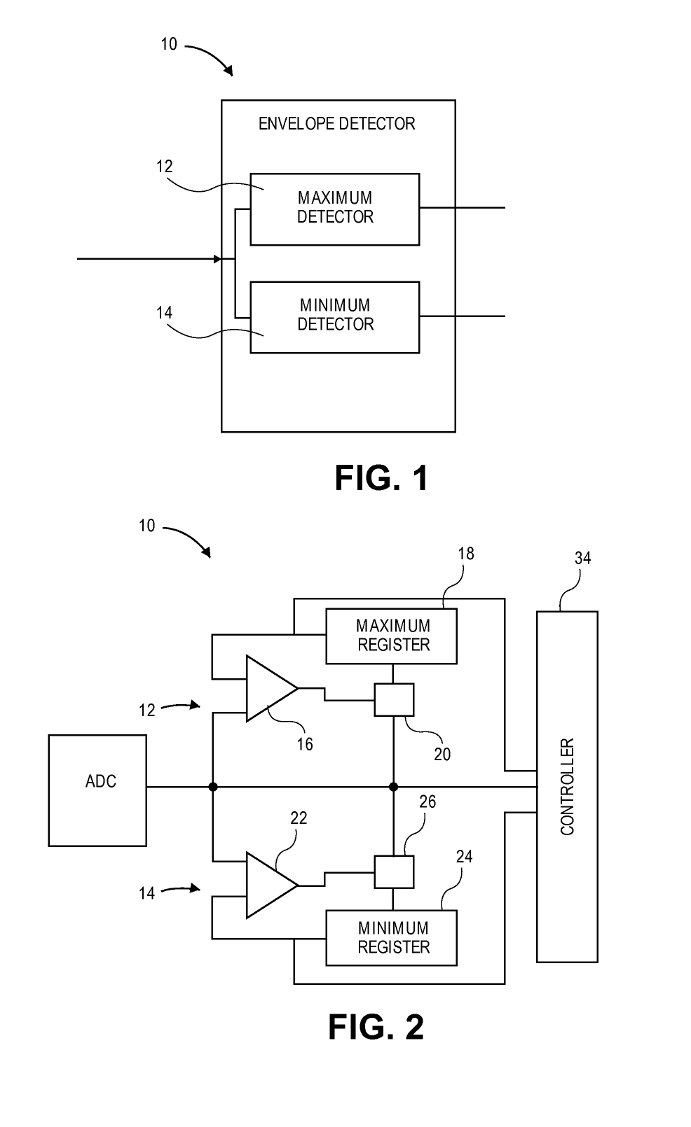

Referring to FIGS. 1-3, the envelope detector 10 may generally include a maximum detector 12 operable to detect the maximum data value present in a data stream and a minimum detector 14 operable to detect the minimum data value present in the data stream. In some embodiments, the maximum detector 12 and minimum detector 14 may function in combination to generally simultaneously detect the maximum and minimum values within a data stream, as is discussed in more detail below.

The envelope detector 10, maximum detector 12, and minimum detector 14 may be implemented in hardware, software, and combinations thereof. In some embodiments, as discussed below, the envelope detector 10 may be implemented utilizing discrete and/or integrated electrical hardware elements. Additionally or alternatively, the envelope detector 10 may be implemented in programmable logic devices such as field programmable gate arrays (FPGAs) or in software. For instance, the envelope detector 10 may be embodied in a hardware description language (HDL) such as VHDL or Verilog.

The envelope detector 10, and/or portions of the maximum detector 12 and minimum detector 14, is operable to be coupled with a data stream, such as a data bus, signal output, or other conductor or transporter of information. In some embodiments, the envelope detector 10 may be coupled with an analog-to-digital converter (ADC) to generally simultaneously detect the minimum and maximum values converted by the ADC. The envelope detector 10 is preferably configured to sequentially receive a plurality of inputs from the data stream. However, in some embodiments the envelope detector 10 may receive parallel inputs from the data stream.

The maximum detector 12 preferably includes a first comparator 16 and a first memory 18 coupled with the first comparator 16. In some embodiments, the maximum detector 12 may additionally include a first switching element 20 coupled with the first comparator 16 and first memory 18.

The first memory 18 is generally operable to store a first data value corresponding to a maximum data value. The first memory 18 may comprise any element or combination of elements operable to store the first data value. Thus, the first memory 18 may comprise read-only memories, random-access memories, optical memories, magnetic memories, flash memories, register devices, combinations thereof, and the like.

In some embodiments, the first memory 18 may be operable to be reset, such as by resetting the maximum data value to zero in response to a received reset signal. Preferably, the first memory 18 is operable to be reset or zeroed prior to the comparison performed by the first comparator 16 so that subsequent larger values from the data stream may replace the initially stored value.

Preferably, the first memory 18 is operable to output a signal corresponding to its currently stored value and replace its currently stored value with a value from the data stream, as is discussed in more detail below. The first memory 18 may have a plurality of inputs for receiving control signals, such as from the first switching element 20, and for receiving input values from the data stream. The first memory 18 may also have a plurality of outputs for outputting currently stored values to various elements such as the first comparator 16.

Thus, in some embodiments the first memory 18 is coupled with the first comparator 16, the first switching element 20, and the data stream. The first memory 18 may also be operable to store a plurality of values such that new maximum values may be stored without deleting or overwriting previously stored values. Thus, the first memory 18 may be operable to store the maximum value, the second-most maximum value, the third-most maximum value, etc.

The first comparator 16 is generally operable to compare at least two signals and output a first control signal based on the comparison. In various embodiments, the first comparator 16 is operable to compare an input signal from the data stream with the output signal corresponding to the maximum data value stored within the first memory 18. In various embodiments, the first comparator 16 is operable to generally sequentially compare inputs provided by the data stream to the maximum data value stored within the first memory 18.

In some embodiments, the first control signal may be a digital signal such that the first comparator 16 outputs a zero if an input from the data stream is not greater than the maximum data value stored within the first memory 18 and outputs a one if the input from the data stream is greater the maximum data value stored within the first memory 18. However, as should be appreciated, the first comparator 16 may additionally or alternatively output analog signals that indicate the result of one or more comparisons. Further, the first comparator 16 may employ digital signal methods other than the binary signaling discussed above.

The first comparator 16 may be any element or combination of elements operable to compare at least two values and output the first control signal indicating which of the values is greater. In some embodiments, the first comparator 16 may include an operational amplifier arranged in comparison configuration. However, the first comparator 16 is preferably a digital comparator operable to compare digital values from the data stream with those stored within the first memory 18.

The first switching element 20 is coupled with the first comparator 16 and first memory 18 as shown in FIG. 2. The first switching element 20 is generally operable to receive the first control signal from the first comparator 16 and function the first memory 18 to cause the first memory 18 to store the current input from the data stream as the maximum data value. For example, if the first comparator 16 compares a first input from the data stream with the maximum data value stored within the first memory 18 and provides the first control signal indicating that the first input is greater than the currently-stored maximum data value, the first switching element 20 is operable to function the first memory 18 to cause the first input to be stored as the maximum data value.

In some embodiments, the first switching element 20 may be integral with the first memory 18 such that the first memory 18 may be coupled with the first comparator 16 to receive the first control signal directly therefrom and replace or retrain the maximum data value accordingly. Thus, the first switching element 20 is not discrete from the first memory 18 in all embodiments.

The minimum detector 14 preferably includes a second comparator 22 and a second memory 24 coupled with the second comparator 22. In some embodiments, the minimum detector 14 may additionally include a second switching element 26 coupled with the second comparator 22 and second memory 24.

The second comparator 22, second memory 24, and second switching element 26 may be generally similar to the first comparator 16, first memory 18, and first switching element 20 discussed above, with the exception that the second memory 24 stores a minimum data value and the second comparator 22 compares the minimum data value to an input from the data stream to determine the if the input is less than the minimum data value. If the input is less than the minimum data value, then the second comparator 22 generates a second control signal to cause the second memory 24 to store the input as the minimum data value.

The second memory 24 may also be reset in response to a received reset signal. In contrast to the first memory 18 discussed above, the second memory 24 is preferably not zeroed when reset. Instead, upon being reset, the second memory 24 may be initialized to a maximum value, such as the maximum value operable to be stored by the second memory 24, to enable replacement by subsequent smaller input values from the data stream.

Additionally, in some embodiments the initialization values stored within the memories 18, 24 upon being reset may be dynamic or user-defined. For instance, instead of being reset to zero, the first memory 18 may be reset to a first user-defined value such that only data stream inputs that are greater than the first user-defined value are stored within the first memory 18. Similarly, instead of being reset to the maximum value, the second memory 24 may be reset to a second user-defined value such that only data stream inputs that are less than the second user-defined value are stored within the first memory 18. Such functionality enables the envelope detector 10 to determine data envelopes only within user-specified ranges.

Portions of the minimum detector 14 may be integral with portions of the maximum detector 12. For example, in some embodiments the envelope detector 10 may provide a single memory operable to store both the maximum data value and the minimum data value, such that the first memory 18 and second memory 24 are not necessarily discrete. Further, the first switching element 20 and second switching element 26 may also be integrated as a single unit.

In combination, the maximum detector 12 and minimum detector are operable to generally simultaneous compare an input from a data stream to a minimum and maximum value to determine if the input is greater than the maximum value or less than the minimum value. Thus, the envelope detector 10 provided by embodiments of the present invention enables a complete data envelope to be determined.

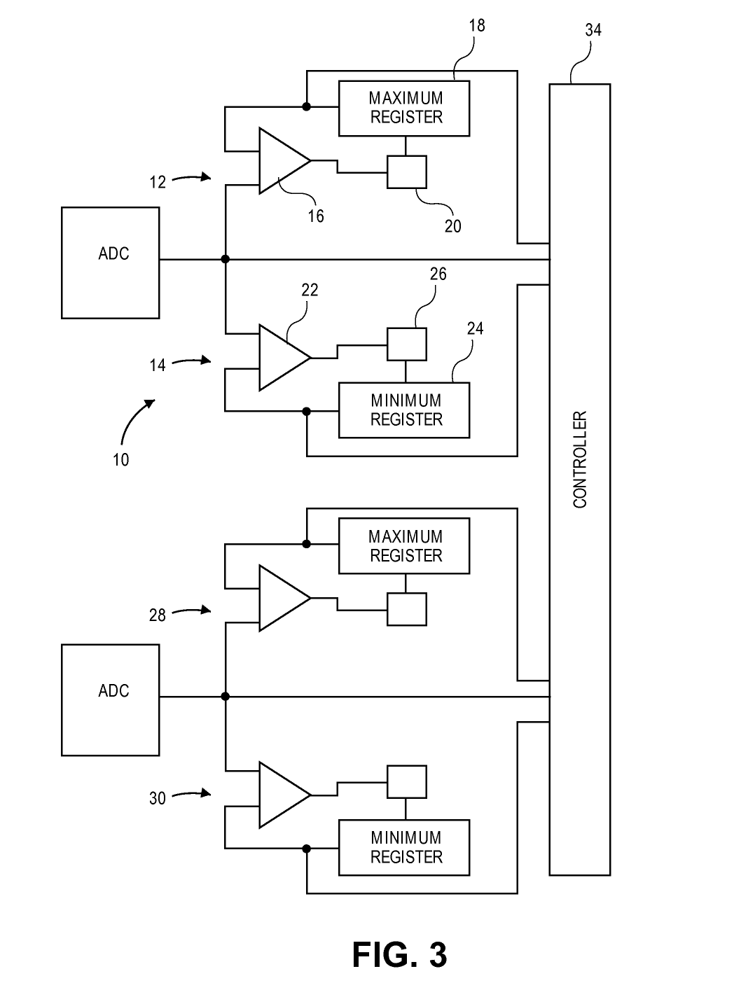

In some embodiments, the envelope detector 10 may include a plurality of minimum and maximum detectors, as is shown in FIG. 3. For example, in addition to the maximum detector 12 and minimum detector 14 discussed above, the envelope detector 10 may include a second maximum detector 28 and a second minimum detector 30. Utilization of a plurality of maximum and minimum detectors enables the envelope detector 10 to receive parallel inputs from one ADC, receive inputs from a plurality of ADCs, and/or determine a plurality of maximums, minimums, second maximums, second minimums, etc.

Further, in some embodiments the envelope detector 10 may include and/or be coupled with a controller 34. The controller 34 may include microcontrollers, microprocessors, discrete logic elements, programmable logic devices, digital signal processing elements, analog and digital components, combinations thereof, and the like. The controller 34 is generally operable to access the data stream, the maximum data value stored within the first memory 18, and the minimum data value stored within the second memory 24.

The controller 34 may access the memories 18, 24 continuously or at periodic intervals to acquire the minimum and maximum data values for any time period. In some embodiments, the memories 18, 24 may be operable to receive one or more reset signals from the controller 34 to reset the maximum and minimum data values. For example, the controller 34 may periodically read the memories 18, 24 to acquire the maximum and minimum data values and then provide a reset signal to reset the maximum and minimum data values stored within the memories 18, 24. Thus, the envelope detector 10 is operable to detect and store a data envelope for a data stream over any time period defined by the controller 34 or a user of the controller 34.

Although the invention has been described with reference to the preferred embodiment illustrated in the attached drawing figures, it is noted that equivalents may be employed and substitutions made herein without departing from the scope of the invention as recited in the claims.

Having thus described the preferred embodiment of the invention, what is claimed as new and desired to be protected by Letters Patent includes the following:

1. An apparatus comprising:
a memory operable to store a first data value and a second data value;
a first comparator coupled with the memory and operable to—
receive an indication of the first data value from the memory,
receive an indication of a first input from a data stream,
compare the first data value to the first input, and
if the first input is greater than the first data value, output a first control signal to cause the memory to store the first input as the first data value; and
a second comparator coupled with the memory and operable to—
receive an indication of the second data value from the memory,
receive an indication of the first input from the data stream,
compare the second data value to the first input, and
if the first input is less than the second data value, output a second control signal to cause the memory to store the first input as the second data value.

2. The apparatus of claim 1, wherein the first comparator is further operable to—
receive an indication of the first data value from the memory,
receive an indication of a second input from the data stream,
compare the first data value to the second input, and
if the second input is greater than the first data value, output the first control signal to cause the memory to store the second input as the first data value.

3. The apparatus of claim 1, wherein the second comparator is further operable to—
receive an indication of the second data value from the memory,
receive an indication of a second input from the data stream,
compare the second data value to the second input, and
if the second input is less than the second data value, output the second control signal to cause the memory to store the second input as the second data value.

4. The apparatus of claim 1, wherein the comparison provided by the first comparator is performed generally simultaneously with the comparison provided by the second comparator.

5. The apparatus of claim 1, wherein the first comparator and second comparator are operable to couple with an analog-to-digital converter to receive the data stream therefrom.

6. The apparatus of claim 1, further including a switching element coupled with the comparators to receive the control signals therefrom, the switching element operable to function the memory to cause the memory to store the first input as the first data value or second data value.

7. The apparatus of claim 1, wherein the memory includes a first memory for storing the first data value and a second memory for storing the second data value.

8. An apparatus comprising:
a first memory operable to store a first data value;
a second memory operable to store a second data value;
a first comparator coupled with the first memory and operable to—
receive an indication of the first data value from the first memory,
receive an indication of a first input from a data stream,
compare the first data value to the first input, and
if the first input is greater than the first data value, output a first control signal to cause the first memory to store the first input as the first data value; and
a second comparator coupled with the second memory and operable to—
receive an indication of the second data value from the second memory,
receive an indication of the first input from the data stream,
compare the second data value to the second input, the comparison of the second data value and the second input occurring generally simultaneously with the comparison provided by the first comparator, and
if the first input is less than the second data value, output a second control signal to cause the second memory to store the first input as the second data value.

9. The apparatus of claim 8, wherein the first comparator is further operable to—
receive an indication of the first data value from the first memory,
receive an indication of a second input from the data stream,
compare the first data value to the second input, and
if the second input is greater than the first data value, output the first control signal to cause the first memory to store the second input as the first data value.

10. The apparatus of claim 8, wherein the second comparator is further operable to—
receive an indication of the second data value from the second memory,
receive an indication of a second input from the data stream,
compare the second data value to the second input, and
if the second input is less than the second data value, output the second control signal to cause the second memory to store the second input as the second data value.

11. The apparatus of claim 8, wherein the first comparator and second comparator are operable to couple with an analog-to-digital converter to receive the data stream therefrom.

12. The apparatus of claim 8, further including a switching element coupled with the comparators to receive the control signals therefrom, the switching element operable to—
function the first memory to cause the first memory to store the first input as the first data value when the switching element receives the first control signal, and
function the second memory to cause the second memory to store the first input as the second data value when the switching element receives the second control signal.

13. The apparatus of claim 8, wherein the switching element includes a first switching element coupled to the first comparator and the first memory and a second switching element coupled to the second comparator and the second memory.

14. An apparatus comprising:
a first memory operable to store a first data value;
a second memory operable to store a second data value;
a first comparator coupled with the first memory and operable to—
receive an indication of the first data value from the first memory,
receive an indication of a first input from a data stream,
compare the first data value to the first input, and
if the first input is greater than the first data value, output a first control signal;
a second comparator coupled with the second memory and operable to—
receive an indication of the second data value from the second memory,
receive an indication of the first input from the data stream,
compare the second data value to the second input, the comparison of the second data value and the second input occurring generally simultaneously with the comparison provided by the first comparator, and
if the first input is less than the second data value, output a second control signal;
a first switching element coupled with the first comparator and first memory, the first switching element operable to receive the first control signal and function the first memory to cause the first memory to store the first input as the first data value; and
a second switching element coupled with the second comparator and second memory, the second switching element operable to receive the second control signal and function the second memory to cause the second memory to store the first input as the second data value.

15. The apparatus of claim 14, wherein the first comparator is further operable to—
receive an indication of the first data value from the first memory,
receive an indication of a second input from the data stream,
compare the first data value to the second input, and
if the second input is greater than the first data value, output the first control signal to cause the first switching element to function the first memory to store the second input as the first data value.

16. The apparatus of claim 14, wherein the second comparator is further operable to—
receive an indication of the second data value from the second memory,
receive an indication of a second input from the data stream,
compare the second data value to the second input, and
if the second input is less than the second data value, output the second control signal to cause the second switching element to function the second memory to store the second input as the second data value.

17. The apparatus of claim 14, wherein the first comparator and second comparator are operable to couple with an analog-to-digital converter to receive the data stream therefrom.

18. The apparatus of claim 14, further including a controller coupled with the first memory and the second memory, the controller operable to function the memories to reset the first data value and the second data value.
